(19) United States
(12) Patent Application Publication
(10) Pub. No.: US 2004/0208205 A1
(43) Pub. Date: Oct. 21, 2004

(54) Tuneable vertical cavity laser amplifier

(76) Inventors: Jean-Louis De Bougrenet Fe La Tocnaye, Saint-Renan (FR); Vivien Verbrugge, Brest (FR)

Correspondence Address: MERCHANT & GOULD PC, P.O. BOX 2903, MINNEAPOLIS, MN, 55402-0903, US

(21) Appl. No.: 10/479,822

(22) PCT Filed: Jun. 5, 2002
(86) PCT No.: PCT/FR02/01922

(30) Foreign Application Priority Data
Jun. 5, 2001 (FR) 01/07333

(51) Int. Cl. H01S 3/10; H01S 5/00

(52) U.S. Cl. 372/20

(57) ABSTRACT

The invention concerns a tuneable vertical cavity laser amplifier, comprising, inside the cavity (25) at least an electro-optical element designed to tune the wavelength (λ) of the laser amplifier, at least one of the electro-optical elements including an isotropic material in a transverse plane. The invention also concerns a telecommunication system comprising the tuneable laser amplifier, an array comprising a plurality of laser amplifier and a method for making same.

This invention relates to the domain of optical components, particularly for high-speed optical networks.

More precisely, the invention relates to laser amplifiers with tuneable wavelength.

For the purpose of this description, a laser amplifier means a laser that behaves like a laser source and/or amplifier. When the energy input to the laser is more than a laser excitation threshold specific to the component, the laser usually behaves like a laser source. Under other conditions, it behaves like an amplifier alone.

Tuneable lasers may be put into two main family groups:

edge emitting lasers; and

vertical cavity lasers.

Tuneable semiconducting laser amplifiers are usually obtained using edge emitting lasers of the DBR (Distributed Bragg Reflector) type. DBRs are described particularly in the “Tune In!” document written by P. Heywood in April 2000 and that can be seen on the www.lightreading.com site. One of the main disadvantages of structures according to prior art is that they have a small tuneable range (of the order of 10 nm) in their elementary form.

The document by P. Heywood mentioned above shows that larger values (for example 40 nm) may be obtained with SSG (Super Structure Grating) and GCSR (Grating-assisted Co-directional Coupler with Sampled Reflector) DBRs. Nevertheless, one disadvantage of these techniques is their higher manufacturing cost, particularly for high-speed telecommunication applications, and particularly for WDM (Wavelength Division Multiplexing).

In this context, VCSELs (Vertical Cavity Surface Emitting Laser) and/or VCAs (Vertical Cavity Amplifier) have many advantages compared with their corresponding edge emitting lasers, particularly including a greater spectral selectivity, a better modal adaptation with fibres due to the circular and only slightly divergent nature of the emitted beam, a single mode transverse and longitudinal behaviour, a possible arrangement in matrix form, particularly a significantly lower manufacturing cost for comparable performances, without forgetting the possibility for an amplifier of a gain between an input and output signal of the order of 30 dB (as indicated particularly in the “Vertical cavity amplifying photonic switch” article, written by Raj, Oudar and Bensoussan and published in the Applied Physical Letters journal on Oct. 31, 1994 by the American Institute of Physics).

It has been demonstrated that the wavelength can be tuned using these structures and various techniques, particularly described in the following articles:

“10.1 nm range continuous wavelength-tuneable vertical-cavity surface-emitting lasers” written particularly by L. Fan and M. C. Wu and published in the Electronics Letters journal (Vol. 30, No. 17, pp 1409-1410, 1994); and

“Tuneable Extremely Low Threshold Vertical-Cavity Laser Diodes” written particularly by T. Wipiejewski and K. Panzlaff and published in the IEEE Photonics Technology Letters journal (Vol. 5, No. 8, pp 889-892, 1993).

However, performances in terms of the tunability range remain modest. They can be improved by inserting an inactive zone in the cavity to perform the tunability function. Several implementations have been proposed based on this principle, mainly:

VCSELs with the MEMS (Micro Electro-Mechanical Systems) technology described by D. Vakhshoori in the “2 mW CW single mode operation of a tuneable 1550 nm VCSEL, with 50 nm tuning range” document and published in the Electronics Letters journal (Vol. 35, pp 900-901, 1999); and

FFPSELs (fibrous surface emitting lasers) described by K. Hsu and C. M. Miller in the “Continuously Tuneable Photopumped 1.3 μm Fibre Fabry-Perrot Surface Emitting Lasers” in the IEEE Photonics Technology Letters journal (Vol. 10, No. 9, pp 1199-1201, 1998).

The MEMS technology is based on the use of DBRs micro-mirrors in which a mechanical displacement modifies the thickness of an air layer.

The MEMS technology has several disadvantages, and particularly high complexity, high cost and mechanical fragility.

FFPSEL devices are also based on the use of DBR, quantum wells and an air thickness.

The FFPSEL technology also has several disadvantages, particularly high cost, the need for good control of the cavity alignment and stability and a large time necessary to change the wavelength (of the order of one millisecond).

One of the various aspects of the invention is to overcome these disadvantages of prior art.

More precisely, one purpose of the invention is to supply an easily tuneable laser amplifier.

Another purpose of the invention is to provide such a laser that is very compact and robust.

Another purpose of the invention is to provide such a laser with good mechanical stability.

Another purpose of the invention is to provide a laser amplifier that is particularly well adapted to high-speed telecommunication applications.

Note that such a laser amplifier can be very selective in wavelength, but covers a wide band due to tunability.

Another purpose of the invention is to provide such a tuneable laser amplifier at low manufacturing cost and installation cost.

Another purpose of the invention is to enable industrialisation of the component so that it can be made at low cost.

Another purpose of the invention is to provide a tuneable laser amplifier capable of changing the wavelength at high speed.

A supplementary purpose of the invention is to provide a tuneable laser amplifier with a good longitudinal overlap factor.

Another purpose of the invention is to provide such a laser capable of exhibiting a high gain when it behaves like an amplifier.

These purposes and others that will become clear later are achieved according to the invention using a vertical cavity laser amplifier, remarkable in that it comprises at least one electro-optic element inside the cavity designed to tune the laser amplifier wavelength.

According to one particular characteristic, the laser amplifier is remarkable in that it also comprises means of application of a variable electric field to electro-optic elements as a function of at least one electrical voltage applied to the laser amplifier.

According to one particular characteristic, the laser amplifier is remarkable in that at least one of its electro-optic elements comprises an isotropic material in a transverse plane.

Note that in this case “transverse plane” means a plane perpendicular to an axis of propagation of the laser beam(s) passing through it.

Thus, in particular for use of the laser in an amplifier mode, with the invention there is advantageously no need to control the polarisation before the laser input, or if the polarisation is arbitrary, there is no need to separate the different polarisations at the output to overcome a polarisation mode dispersion (which would require an additional component).

Note that in this case “isotropic material” means an isotropic material means a material that is isotropic at the wavelength(s) considered (in other words at the wavelength(s) emitted by the laser amplifier).

Note also that the material is isotropic in a transverse plane, which is sufficient to obtain an amplifier with a behaviour insensitive to the polarisation.

According to one particular characteristic, the laser amplifier is remarkable in that at least one of the electro-optic elements comprises a nano-PDLCC type material.

The result is advantageously a material with good optical characteristics, and that is easy to implement.

According to one particular characteristic, the laser amplifier is remarkable in that it behaves like an amplifier.

According to one particular characteristic, the laser amplifier is remarkable in that it behaves like a laser generating at least one laser beam.

Thus, the invention is advantageously compatible with the different possible operating modes of a laser amplifier that can be used as an amplifier alone, as a beam generator laser alone, or as an amplifier and a beam generator laser depending particularly on its bias (electrical or optical) (depending on the pumping type) compared with the laser threshold.

According to one particular characteristic, the laser amplifier is remarkable in that it comprises transparent or semi-transparent electrodes enabling the application of the electric field(s) to the electro-optical element(s) and the passage of light beams through these electrodes.

Thus, light beam(s) emitted by the laser amplifier can pass through the electrodes, which can also create an appropriate electric field in the electro-optic element.

According to one particular characteristic, the laser amplifier is remarkable in that the electrodes are of the ITO (Indium-Tin Oxide) type.

The result is advantageously electrodes with good optical properties and that are easy to use, for example by deposition and etching.

According to one particular characteristic, the laser amplifier is remarkable in that it also comprises at least one electrode enabling electrical pumping of the cavity.

Thus, the laser amplifier is relatively easy to make and there is no need to add an optical pump to it, which means that the installation cost can be low.

The invention also relates to a matrix of components remarkable in that the matrix comprises at least two laser amplifiers.

According to one particular characteristic, the components matrix is remarkable in that each laser in the matrix comprises means of applying an electric field for tuning a wavelength associated with the laser, such that the matrix can tune several wavelengths.

Thus, the invention provides a means of obtaining low cost components.

The invention also supplies a component capable of generating and/or amplifying one or several laser beams with several wavelengths tuned independently of each other.

The invention also relates to a high speed telecommunications system characterised in that it comprises at least one laser amplifier as described previously, cooperating with at least one optical fibre for emitting at least one light beam emitted by the laser amplifier.

The advantages of telecommunication systems are the same as the advantages of a laser amplifier, and are not described in more detail.

Furthermore, the invention relates to a process for making a tuneable vertical cavity laser amplifier, characterised in that it comprises:

a step for making a first part of the laser amplifier comprising at least one first electrode;

a step for making a second part of the laser amplifier comprising at least one second electrode;

a step for making a cavity itself obtained in a sub-step in which the first and second parts are assembled; and

a step in which the cavity is filled by at least one electro-optic element.

Thus, the result is an advantageous method of making a laser amplifier that is easy to implement, reliable and low cost.

According to one particular characteristic, the manufacturing process is remarkable in that it also comprises a step for depositing an element on at least one part of the laser for assembly and for filling.

Preferably, an element that is economic and easy to deposit and etch is used, for example of the polyimide type.

Other characteristics and advantages of the invention will become clearer after reading the following description of a preferred embodiment given as a simple illustrative and non-limitative example and the appended drawings, wherein:

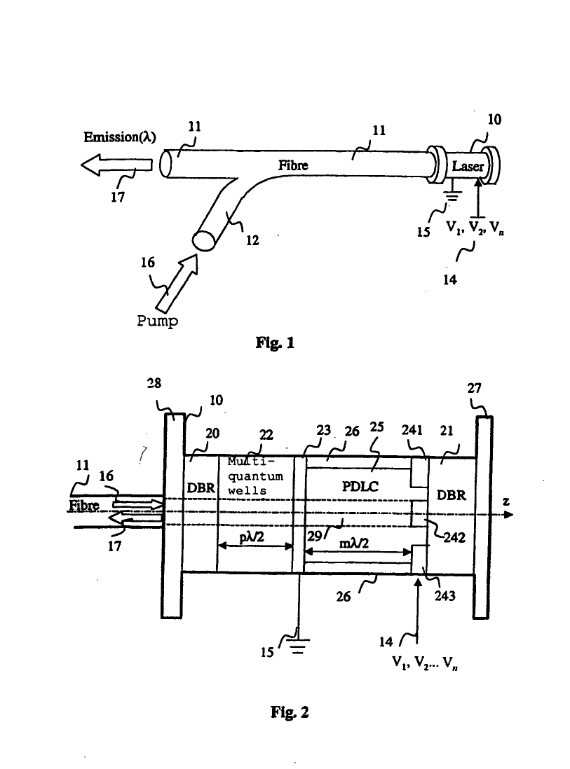

FIG. 1 shows a general perspective view of one particular embodiment of a laser amplifier associated with an optical fibre according to the invention;

FIG. 2 illustrates a principle diagram of the laser amplifier in FIG. 1;

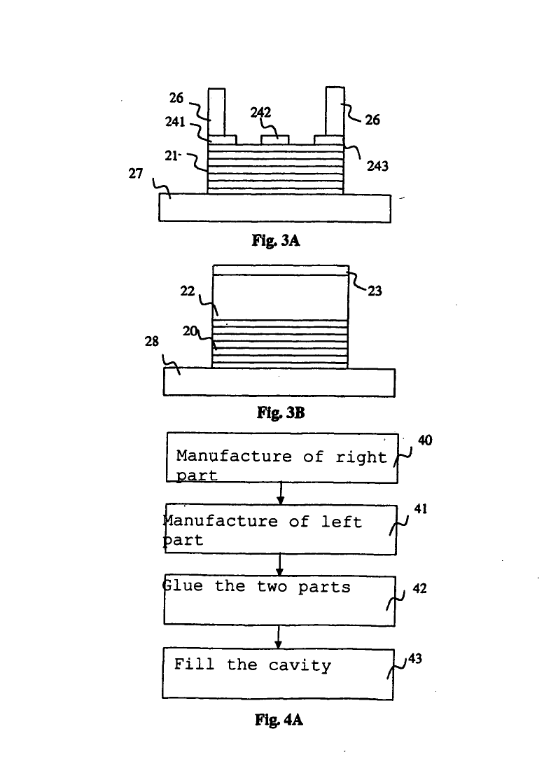

FIGS. 3A and 3B describe part of the laser amplifier in FIGS. 1 and 2 more precisely;

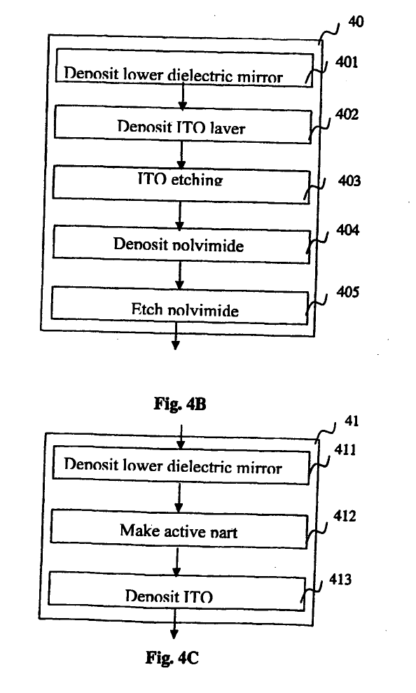

FIGS. 4A, 4B and 4C present a process for making the laser amplifier in the previous figures;

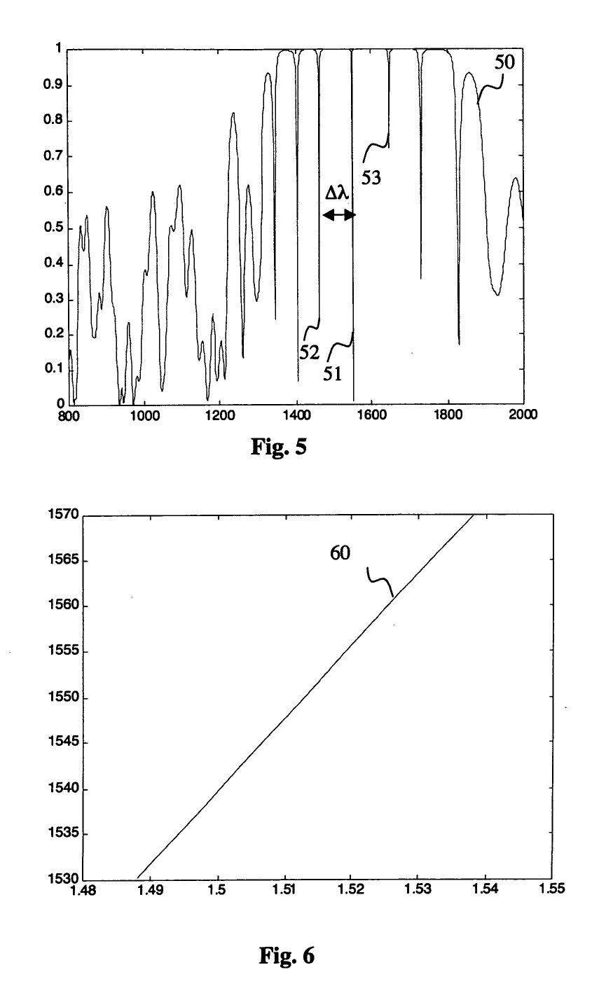

FIG. 5 illustrates a spectrum of the reflection coefficient of the tuneable laser amplifier in FIGS. 1 and 2;

FIG. 6 shows the emission wavelength as a function of the index of the nano-PDLC layer illustrated in FIG. 2;

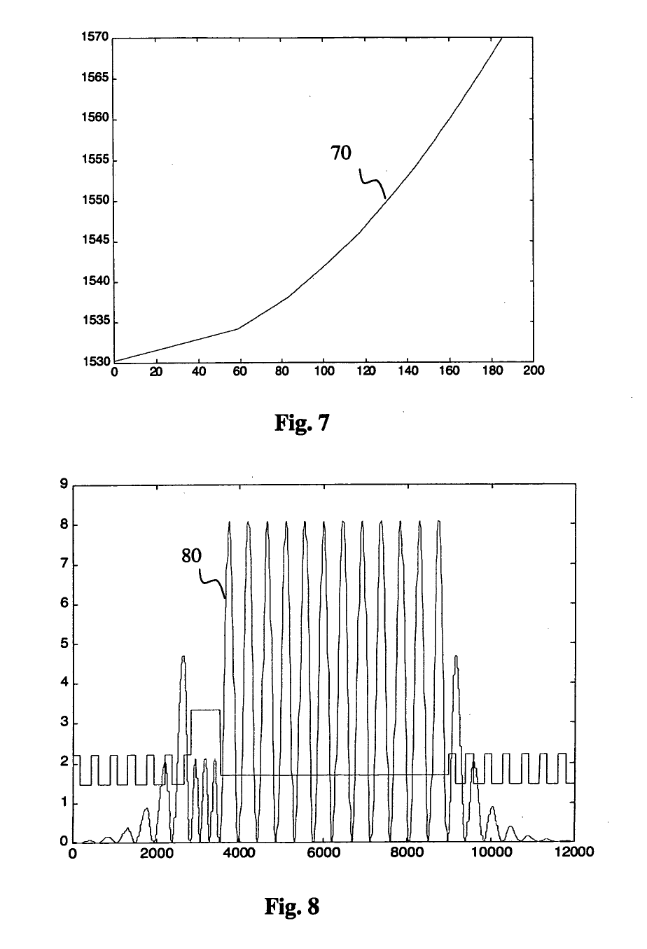

FIG. 7 illustrates the emission wavelength as a function of polarisation voltage of the nano-PDLC layer illustrated in FIG. 2;

FIG. 8 gives an example of a variation of the intra-cavity stationary field in the structure defined in FIG. 2.

General Principle of the Invention

The general principle of the invention is based on a combination of:

an active element, for example of the multi-quantum well type; and

a phase shift area comprising an electro-optic element;

the assembly forming a cavity.

The active element and the phase shift area are included between two DBR mirrors to generate and/or amplify a light beam at a given wavelength that depends on the optical thickness of the cavity through which the beam passes (remember that the optical thickness is equal to the product of the physical thickness and the index of the medium).

This phase shift area is subjected to one or several electric fields on which action can be taken by means of electrodes for which the voltage is to be controlled. The index of the phase shift area and therefore its optical thickness can vary as a function of the voltage applied to the electrodes. The result is thus a low cost, reliable, compact tuneable laser amplifier with a high wavelength change speed (of the order of 10 μs).

It is also possible to obtain a matrix of such components, therefore emitting several wavelengths by having separate electrodes and having different electric potentials, each of these electrodes generating distinct fields within the phase shift area.

Characteristic Values

The manufacture of laser amplifiers according to the invention requires a correct choice of some parameters, particularly depending on the tunability range of the laser amplifier. Characteristic formulas (variation of the wavelength, Free Spectral Range (FSR), longitudinal overlap factor) essential for studying the required function and implementation of the invention, will be presented.

Variation of the Wavelength

The variation of the wavelength λ of the component consecutive to a variation of the index n of the phase shift layer is given by the following equation:

$$\frac{Δ λ}{λ} = \frac{m}{m + p + {\sum }_{i} {L}_{pen . i} \frac{{n}_{m . i}}{λ}} \cdot \frac{Δ n}{n} \qquad relation ( 1 )$$

where:

m and p are integers characterising the thickness of the layers in the cavity described below, particularly with respect to FIG. 2;

L_{pen.i} is the wave penetration length and n_{m.i} is the average index of the i^{th} Bragg mirror considered (the first Bragg mirror being numbered i equal to 1 and the second i equal to 2).

We considered the case of dielectric Bragg mirrors with materials with very different indexes and therefore low penetration lengths.

Therefore relation (1) can be rewritten in the form:

$$\frac{Δ λ}{λ} = \frac{m}{m + p} \cdot \frac{Δ n}{n} \qquad relation ( 2 )$$

Free Spectral Range

The free spectral range (or FSR) of the structure is given by:

$$FSR = \frac{{λ}^{2}}{2 {n}_{eff} \cdot ( {L}_{pen .1} + {L}_{pen .2} + {L}_{cav} )} \qquad relation ( 3 )$$

where L_{cav} and n_{eff} are the cavity length and the average index of the effective cavity formed by the cavity and the penetration lengths in the mirrors, respectively.

Longitudinal Overlap Factor

Finally, we would be interested in the longitudinal overlap factor characterising the proportion of the intra-cavity stationary field located on quantum wells, so that we can characterise the gain medium composed of quantum wells that is the basis for the laser emission. Obviously, this factor varies with the variation of the index of the phase shift layer and is given by:

$$Γ = \frac{{\int }_{cavity}^{} QW ( z ) {\vert \vec{E} ( z ) \vert}^{2} ⅆ z}{{\int }_{cavity}^{} {\vert \vec{E} ( z ) \vert}^{2} ⅆ z} \qquad relation ( 4 )$$

where E(z) is the stationary field in z (longitudinal axis of the beam) and QW(z) is a function equal to 1 on quantum wells and 0 elsewhere.

The integration is made over the entire cavity, including the penetration length into mirrors.

Nano-PDLC Modulator

The electro-optic component is composed of a Polymer Dispersed Liquid Crystal (PDLC) mix described particularly by S. Matsumoto in the “Nanosize fine droplets of liquid crystal for optical application” article published in “Material Research Society Symposium Proceeding” document, Vol. 457, 1997).

The size of nano-PDLC liquid crystal droplets is between 100 and 200 nanometres, unlike the standard PDLC in which the size of the droplets is several microns.

When there is no electric field, the nano-PDLC is isotropic in all directions. However, if an electric field E is applied, the nano-PDLC crystals are oriented isotropically in a plane perpendicular to the field.

Considering the dimensions of the droplets with respect to the wavelength (about 1550 nm), the material behaves like an isotropic material in a transverse plane (in other words in a plane perpendicular to the electric field that is in the same direction as the laser beam generated and/or amplified by the component), for which the index can be modified with the electric voltage applied to it.

The index modulation for a nano-PDLC is given by the following relation:

Δn=kE_{—} relation (5)

where E is expressed in V/μm and k is a constant proportional to the dimension and density of the droplets. The value of k is usually between 10⁻⁵ and 2×10⁻⁴ for ne equal to 1.716 and no equal to 1.513. With a field of 30 V/μm, it is also possible to obtain a modulation of the index no of more than 12% for k equal to 2×10⁻⁴ and 0.6% for k equal to 10⁻⁵. If we consider that for a cavity width 1, the spectral modulation Δλ/λ is very large compared with the width of the quantum wells area L, given as a first approximation by the following relation:

Δλ/λ=Δn/n relation (6)

the resulting tunability is between 0.6% and 12%, equivalent to a variation in the wavelength Δλ between 9 and 180 nm at 1.55 μm for an index no equal to 1.513.

If we consider an applied field of 30 V/μm and a nano-PDLC layer with an optical thickness of 6λ as an example, all that is necessary to obtain the entire wavelength range is to apply a voltage of between 0 V and 185 V.

Note that the material used is generally:

macroscopically spatially isotropic (case particularly for nano-PDLC at 0 V); or

simply isotropic in a transverse plane (in other words in a plane perpendicular to the axis of the propagation of the laser beam) (for example, the case of the nano-PDLC for which an electric field is applied oriented along the propagation axis).

The voltage cannot be increased indefinitely; thus, the saturation effect of reorientation of the liquid crystal limits the variation range of the index.

Making a Laser Amplifier According to the Invention

We will now present a preferred embodiment of a tuneable laser amplifier 10 associated with an optical fibre 11, with reference to FIG. 1.

Note that the laser amplifier 10 is subjected to different electrical potentials, one of the points 14 being subjected to potentials V1, V2, . . . Vn (where n can vary from 1 to several hundred) and a zero potential is applied to the other point 15.

The laser amplifier 10 is connected to n fibres. For reasons of clarity, only one fibre 11 was shown in FIG. 1.

Note that the fibre 11 cooperates with the laser amplifier 10 at one of its ends and it emits a laser beam 11 emitted by the laser amplifier 10 at its other end.

A fibre 12 powers the laser amplifier 10 through the fibre 11 with a pump 16.

According to a first variant of the invention, n is equal to 1, only one fibre is connected to the component 10 and the point 14 is subjected to a single potential V.

FIG. 2 diagrammatically illustrates the principle of the laser amplifier as illustrated in FIG. 1, in the form of a longitudinal section.

The laser amplifier comprises a cavity closed by two DBR type mirrors:

a first dielectric mirror 21 with 8 layers and held in contact with a transparent substrate 27; and

a second dielectric mirror 20 with 7 layers and held in contact with a transparent substrate 28.

These two mirrors 20 and 21 are perpendicular to the longitudinal z axis along which the laser beam is emitted (they are in a transverse plane).

The laser amplifier 10 is optically pumped by the second mirror 20. This also enables collection of the laser emission through appropriate optics (for example coupling micro-lenses).

Thus, the mirrors are calculated to be:

highly reflective at 1.55 μm (99.5% reflectibility for the second mirror 20 and 99.8% for the first mirror 21); and

transparent at 980 nm (the reflectivity is less than 5%).

The indexes for the materials used in each of the mirrors 20 and 21 are assumed to be equal to 1.47 for the lowest index and 2.23 for the other index.

The cavity comprises the following elements in sequence:

a first electrode 23 connected to a zero electric potential;

a nano-PDLC area 25;

a set of n electrodes (of which only three electrodes 241, 242 and 243 have been shown for reasons of clarity) in the form of rectangular modules parallel to each other and perpendicular to the z axis (typically with length and width of more than 20 μm to enable a voltage to be applied in a cavity with a diameter of between 10 and 20 μm); and

a quantum wells area 22.

Non-zero potentials V1, V2 and V3 are applied to electrodes 241, 242 and 243.

According to the first variant embodiment, the set of three electrodes 241, 242 and 243 is replaced by a single electrode at a non-zero potential V.

The nano-PDLC area 25 with an optical thickness of 6λ, which is about 6.15 μm thick for an index no equal to 1.513, is sandwiched between the electrode 23 and the ITO type electrodes 241, 242 and 243. It can be considered that each parallelepiped shaped nano-PDLC band parallel to the z-axis and included within the area 25 between an electrode 241, 242 and 243 at voltages V₁, V₂ and V₃ respectively and the electrode 23, is subjected to a practically constant field equal to E₁, E₂ and E₃ respectively (for example, the band between the electrode 242 and electrode 23 is shown in FIG. 2 as a band 29 delimited by dashed lines). Thus, each of these nano-PDLC bands has its own index equal to n₁, n₂ and n₃ respectively, and that can be tuned independently with a single component, to wavelengths λ₁, λ₂ and λ₃. Thus, a beam with a precise wavelength can be emitted to each of the fibres associated with the component, the wavelength being tuned as a function of the potential Vᵢ applied to the corresponding electrode independently of the other beams. Note that consequently in FIG. 2, the fibre 11 transmits a laser beam for which the wavelength is tuned by electrode 242 (which is aligned with fibre 11 along the propagation axis of the beam).

According to the first variant embodiment, the entire nano-PDLC area 25 is subjected to an almost constant field equal to E. In this case, the nano-PDLC layer has a single index and tunes a single wavelength.

The electrodes are thin enough (a few tens of nanometers) so that they can be considered as being transparent).

The active area 22 is made in quaternary 1.18 with optical thickness of 1.5 λ, which is about 0.7 μm for an index equal to 3.33.

This active area 22 contains multi-quantum wells (five 7 nm wide wells with 10 nm barriers for each multi-quantum well) placed on the maxima of the intra-cavity field when polarisation of the phase shift area is at mid-travel distance. The result is thus a periodic gain.

The weakness of the reflection at the semiconductor/nano-PDLC interface provides a means of getting around the anti-reflection treatment that would complicate the structure and reduce the longitudinal overlap factor for the same cavity length and phase shift area.

However, an anti-reflection treatment can be used in some embodiments.

Pumping is done at the same side as the active area. The second mirror 20 is held in contact with the fibre 11 and its reflectivity is less than the reflectivity of the first mirror 21 to facilitate emission on the side of the structure on which the active area is located in order to reduce absorption of the pump by the nano-PDLC area. In general, a mirror with a lower reflectivity will be chosen on the side on which the emission is to take place.

The relative thickness of the two elements making up the cavity is chosen by making a compromise between:

a reasonable value of the active thickness (in other words thick enough) to obtain a reasonable overlap factor and therefore a conventional laser threshold; and

the largest possible phase shift area to obtain the largest possible tunability range.

The total thickness is chosen to be sufficiently low to obtain an FSR compatible with tunability (in other words FSR larger than the tunability band) without a mode skip and possible nano-PDLC polarization voltage. According to the relation (3) mentioned above, the FSR is inversely proportional to the cavity length. Therefore, FSR is large enough because the cavity is short.

The following parameters characterize the laser amplifier 10:

glass index (substrate): 1.5;

DBR high index: 2.23;

DBR low index: 1.47;

quaternary index: 3.33;

InGaAs index (quantum well): 3.56;

nano-PDLC no index: 1.513;

p: 3;

m: 12;

number of pairs of DBR 20: 7;

number of pairs of DBR 21: 8;

k: 5.5.10-5; and

applied field: 30 V/μm.

Making the Different Parts of the Component

FIG. 3A more precisely describes the isolated end of the laser amplifier 10 and FIG. 4B describes its embodiment.

Manufacturing 40 of the isolated end of the component (right part in FIG. 2) requires several steps.

During a first step 401, the first dielectric Bragg mirror 21 is deposited on an optical quality glass plate 27 by vacuum deposition.

Then in a step 402, a thin layer of ITO is deposited, making up the first electrode that polarizes the nano-PDLC layer.

Then during step 403, the ITO layer is etched to produce electrode bands (241, 242, 243) that can be polarised independently. Therefore, this step produces a strip of independent components and more generally provides a means of making the independent components matrix.

A sacrificial layer (26) of polyimide is then deposited in step 404 using a spinner, with its thickness controlled to within 2%.

Then in step 405, this layer is selectively etched to leave pads that are then used to glue this part to the second part of the laser amplifier 10, leaving a space with a thickness controlled to within 2% in the cavity that could be filled with nano-PDLC.

FIG. 3B more generally describes the end of the laser amplifier 10 through which the laser beam is emitted and FIG. 4C shows how it is made.

The uninsulated end of the component (left part in FIG. 2) will be manufactured 41 in several steps.

During a first step 411, the second dielectric Bragg mirror 20 is deposited on an optical quality glass plate 28 by vacuum deposition.

The active part 22 of the component is then grown by resumed epitaxy during step 412.

A thin layer of ITO is then deposited to form the electrode 23, in step 413.

FIG. 4A more globally describes the manufacture of the laser amplifier 10.

During the first two steps 40 and 41, the two parts of the component are made as illustrated with reference to FIGS. 4B and 4C.

Then, the two parts of the component thus made are glued together during step 42.

Then during a step 43, the cavity formed by assembling the two parts together is filled by nano-PDLC in the form of liquid crystal droplets dispersed in a liquid polymer, and the polymer is left to polymerise.

Note that after step 42, each of the crystal droplets has isotropic properties in one plane but its optical index is different in the perpendicular direction. Nevertheless, the cavity is macroscopically isotropic. Thus, the cavity does not introduce any optical polarization.

The error on the thickness of the phase shift layer was simulated and a difference of about 1 nm on the resonant wavelength was found for each percent error in thickness, provided that the error does not exceed 5%. Thus, the loss of tunability is of the order of one nanometer, which is negligible compared with the band considered. Therefore, the thickness error envisaged of less than 2% is negligible for correct operation of the component (despite the fact that the index (1.513) of the area controlling tunability is larger than the index for MEMS type structures (tunability obtained by modulating an air gap)).

The laser amplifier 10 was simulated using the propagation matrices product method. FIG. 5 shows the reflectivity spectrum 50 of the component by polarization of the phase shift area such that the emission is centred at 1.55 μm. The abscissa axis represents the wavelength expressed in nanometers, while the ordinate axis represents the reflection coefficient in intensity.

The peaks (with a reflection coefficient close to 0) correspond to wavelengths that can be amplified by the laser amplifier 10. A resonant peak 51 can be observed at 1.55 μm. An FSR (Free Spectral Range as defined earlier) (corresponding to the difference between the wavelength associated with the resonant peak 51 and the wavelength associated with the closest resonant peak 52 or 53) is observed greater than 45 nm.

FIG. 6 shows the variation 60 of the emission wavelength of the component 10 (expressed in nanometers on the ordinate axis) as a function of the index of the nano-PDLC layer. A tunability range of about 40 nm can be observed. Thus, the FSR (more than 45 nm) is comfortably compatible with the tunability range shown in FIG. 6.

It can be observed that this tunability curve is practically linear with the index. The variation of the index chosen extends over 3% of its value, which corresponds to a k value equal to 5.5×10⁻⁵, an applied field of 30 V/μm and a nano-PDLC index of 1.513. It can be observed that there is no mode skip phenomenon in this case. This is due to the high FSR of the cavity. For the same applied field, it can vary from about 9 nm to 180 nm for values of k varying from 10⁻⁵ to 2×10⁻⁴′ assuming that expression (6) is valid and that the saturation area given in expression 5 is not applicable.

FIG. 7 shows the variation 70 of the emission wavelength of the component (expressed in nanometers on the ordinate axis) as a function of the polarization voltage (expressed in volts on the abscissa axis). The curve 70 is calculated under the same conditions as curve 60 in the previous figure. Less than 185 V is sufficient to obtain the required tunability range.

FIG. 8 shows the variation 80 of the intensity of the intra-cavity stationary field in the different component layers characterised by their corresponding indexes.

It can be seen that the PDLC area 25 “consumes” a large part of the intensity, and reduces the overlap factor correspondingly. If the index of this area is lower, the intensity in this area would be greater still due to more intense minima and a greater physical thickness for the same optical thickness, causing an even smaller confinement factor. This clearly confirms the advantage of this structure over structures that are tuned through an air zone. The result is a confinement factor Γ equal to 0.005 when the emission is centred at 1.55 μm, while the value obtained would be Γ=0.0015 if the phase shift layer was composed of air as in a MEMS.

Obviously, the invention is not limited to the example embodiments mentioned above.

In particular, those skilled in the art can produce many variants in the form of the structure of the laser amplifier, the composition of the variable index area.

Similarly, the manufacturing method is not limited to the method described but any manufacturing method can be used provided that it enables the combination of a laser and an electro-optical material that is preferably isotropic along a plane perpendicular to propagation of the light beam(s) and to which at least one electric field can be applied along the axis of propagation of the light beam(s).

The invention is also applicable to the case in which emission and/or pumping can be done at both ends of the laser or the case in which pumping is done at one end of the laser and emission is done at the other end.

The invention is also equally applicable to the case in which the electro-optical area is composed of a material that is not nano-PDLC, while having isotropic electro-optical properties in a transverse plane.

Obviously, the invention is also applicable to the case in which the geometries of the electrodes are different from the geometries described (provided only that they enable application of an electric field parallel to the axis of propagation of the laser beam) and/or they are composed of a material that is transparent or semi-transparent for laser beams, but not of the ITO type.

The invention is also applicable to the case in which the other parts of the laser component are different from those in the described embodiment, particularly for the active area or ends. In particular, these ends could be made from a material different from the material of the glass fibre or substrate and in particular would be transparent or quasi-transparent at the end (or ends) through which the laser emission is done, and if applicable through which pumping is done.

For example, according to the invention, the Bragg mirrors are not necessarily dielectric DBRs, but they can equally well be semiconducting DBRs.

The invention is also applicable not only to the case in which the component is directly coupled to one or several fibres (the component is then sufficiently close to the fibre(s) such that the air diffraction effect is negligible) or with an interface comprising one or several collimators (in the form of an optical network or a coupling lens), but also to any other laser beam transmission medium, particularly such as free air (in this case, a collimated pump slightly shifted by a given angle can be used, passing through a collimation micro-lens before penetrating into the component; a separator cube polarised with a polarised pump, or any other solution by which an optical pump can be inserted into the component, can also be used).

The invention is not limited to the case of optical pumping of the cavity. It is also applicable to electrical pumping of the cavity by means of another electrode. In particular, this electrode may be located between the DBR at the laser emission end, and the quantum wells. The energy added by means of a voltage applied to the quantum wells is also electrical and does not require the use of a laser pump which may be expensive. If a component is made using electric pumping, a cavity definition step is necessary, for example by implantation of protons (defining an isolating area around the cavity) or by selective oxidation of a layer of the component leaving a material disk not oxidised.

The invention is used for applications in the telecommunications field (particularly for the transmission of low or high speed data, the transmission of data on multimode fibres, etc.), and also in many other domains using laser beams.

1. Vertical cavity laser amplifier,
characterised in that inside the said cavity (25) it comprises at least one electro-optic element designed to tune the wavelength (λ) of the said laser amplifier, at least one of the said electro-optic elements comprising an isotropic material in a transverse plane.

2. Tuneable vertical cavity laser amplifier according to claim 1, characterised in that it also comprises means of application (23, 241, 242, 243, 15, 14) of a variable electric field to the said electro-optic element as a function of at least one electrical voltage (V₁, V₂, Vₘ) applied to the said laser amplifier (10).

3. Laser amplifier according to claim 1, characterised in that each of the said at least one electro-optic element is entirely made from an isotropic material in a transverse plane.

4. Laser amplifier according to claim 1, characterised in that at least one of the said electro-optic elements comprises a nano-PDLC type material.

5. Laser amplifier according to claim 1, characterised in that it behaves like an amplifier.

6. Laser amplifier according to claim 1, characterised in that it behaves like a laser generating at least one laser beam.

7. Laser amplifier according to claim 1, characterised in that it comprises transparent or semi-transparent electrodes (23, 241, 242, 243) enabling application of the said at least one electric field to the said electro-optical element(s) and the passage of light beams through these electrodes.

8. Laser amplifier according to claim 7, characterised in that the said electrodes are of the ITO type.

9. Laser amplifier according to claim 1, characterised in that it also comprises at least one electrode enabling electrical pumping of the said cavity.

10. Matrix of components characterised in that the said matrix comprises at least two laser amplifiers according to claim 1.

11. Matrix of components according to claim 10, characterised in that each laser of the said matrix comprises means of applying an electric field for tuning a wavelength associated with the said laser, such that the said matrix can tune several wavelengths.

12. High speed telecommunications system, characterised in that it comprises at least one laser amplifier (10) according to claim 1, cooperating with at least one optical fibre (11) for emitting at least one light beam emitted by the said laser amplifier.

13. Process for making a vertical cavity laser amplifier, characterised in that it comprises:
a step (40) for making a first part of the said laser amplifier comprising at least one first electrode;
a step (41) for making a second part of the said laser amplifier comprising at least one second electrode;
a step (42) for making a cavity itself obtained in a sub-step in which the first and second parts are assembled; and
a step (43) in which the cavity is filled by at least one electro-optic element.

14. Process according to claim 13, characterised in that it also comprises a step for depositing (404) an element on at least one of the said parts of the said laser, for said assembly and for said filling.

15. Process according to claim 13, characterised in that at least one of the said electro-optic elements comprises an isotropic material in a transverse plane.

16. Process according to claim 13, characterised in that at least one of the said electro-optic elements comprises a nano-PDLC type material.
